(19) United States
(12) Patent Application Publication
(10) Pub. No.: US 2017/0057811 A1
(43) Pub. Date: Mar. 2, 2017

(54) DEVICE

(71) Applicant: KABUSHIKI KAISHA TOSHIBA, Tokyo (JP)

(72) Inventor: Yoshiaki SHIMOOKA, Sagamihara Kanagawa (JP)

(73) Assignee: KABUSHIKI KAISHA TOSHIBA, Tokyo (JP)

(21) Appl. No.: 15/068,499

(22) Filed: Mar. 11, 2016

(30) Foreign Application Priority Data
Aug. 26, 2015 (JP) 2015-166699

(51) Int. Cl. B81B 7/00

(52) U.S. Cl. CPC B81B 7/0061; B81B 2207/07

(57) ABSTRACT

According to one embodiment, a device is disclosed. The device includes a substrate, and an element provided on the substrate. The device further includes a film provided on the substrate. The film and the substrate constitute a cavity in which the element is housed. The device further includes a gas absorbing member having a pattern, and provided in the cavity. The gas absorbing member includes a portion exposed to the cavity.

### CROSS-REFERENCE TO RELATED APPLICATIONS

This application is based upon and claims the benefit of priority from Japanese Patent Application No. 2015-166699, filed Aug. 26, 2015, the entire contents of which are incorporated herein by reference.

### FIELD

Embodiments described herein relate generally to a device including an element provided on a substrate.

### BACKGROUND

A device including a microelectromechanical systems (MEMS) element comprises a substrate, a fixed electrode (lower electrode) provided on the substrate, and a movable electrode (upper electrode) provided above the fixed electrode. The MEMS element further comprises, for example, a dome structure (diaphragm) provided on the substrate. For instance, the dome structure and the substrate form a cavity in which the fixed electrode and the movable electrode are housed.

### BRIEF DESCRIPTION OF THE DRAWINGS

FIG. 1 is a plan view schematically illustrating a device according to a first embodiment.

FIG. 2 is a sectional view taken along line 2-2 of FIG. 1.

FIG. 3 is a view for explaining an example of the device comprising a mechanism for enabling a current to flow through a getter member.

FIG. 4 is a view for explaining another example of the device comprising the mechanism for enabling the current to flow through the getter member.

FIG. 5 is a sectional view for explaining a method for manufacturing the device according to the first embodiment.

FIG. 6 is a sectional view for explaining the method for manufacturing the device according to the first embodiment subsequent to FIG. 5.

FIG. 7 is a sectional view for explaining the method for manufacturing the device according to the first embodiment subsequent to FIG. 6.

FIG. 8 is a sectional view for explaining the method for manufacturing the device according to the first embodiment subsequent to FIG. 7.

FIG. 9 is a sectional view for explaining the method for manufacturing the device according to the first embodiment subsequent to FIG. 8.

FIG. 10 is a sectional view for explaining the method for manufacturing the device according to the first embodiment subsequent to FIG. 9.

FIG. 11 is a sectional view for explaining the method for manufacturing the device according to the first embodiment subsequent to FIG. 10.

FIG. 12 is a sectional view for explaining the method for manufacturing the device according to the first embodiment subsequent to FIG. 11.

FIG. 13 is a sectional view for explaining the method for manufacturing the device according to the first embodiment subsequent to FIG. 12.

FIG. 14 is a plan view schematically illustrating a device according to a second embodiment.

FIG. 15 is a sectional view taken along line 15-15 of FIG. 14.

FIG. 16 is a plan view schematically illustrating a device according to a third embodiment.

FIG. 17 is a plan view schematically illustrating a device according to a fourth embodiment.

FIG. 18 is a sectional view taken along line 18-18 of FIG. 17.

FIG. 19 is a sectional view for explaining a method for manufacturing the device according to the fourth embodiment.

FIG. 20A is a sectional view illustrating a sectional shape of a getter member in a through hole of a first cap.

FIG. 20B is a sectional view illustrating a sectional shape of the getter member in the through hole of the first cap.

FIG. 20C is a sectional view illustrating a sectional shape of the getter member in the through hole of the first cap.

FIG. 20D is a sectional view illustrating a sectional shape of the getter member in the through hole of the first cap.

FIG. 21 is a sectional view illustrating a modification of the device according to the fourth embodiment.

FIG. 22 is a sectional view illustrating a device according to an alternative embodiment.

FIG. 23 is a sectional view for explaining a method for manufacturing the device according to the alternative embodiment.

FIG. 24 is a sectional view for explaining the method for manufacturing the device according to the alternative embodiment subsequent to FIG. 23.

### DETAILED DESCRIPTION

In general, according to one embodiment, a device is disclosed. The device includes a substrate, and an element provided on the substrate. The device further includes a film provided on the substrate. The film and the substrate constitute a cavity in which the element is housed. The device further includes a gas absorbing member having a pattern, and provided in the cavity. The gas absorbing member includes a portion exposed to the cavity.

Embodiments will be described hereinafter with reference to the accompanying drawings. The drawings are schematic and conceptual, and the dimensions, the proportions, etc., of each of the drawings are not necessarily the same as those in reality. Moreover, in the drawings, the same numbers represent the same or corresponding portions, and overlapping explanations thereof will be made as necessary.

### First Embodiment

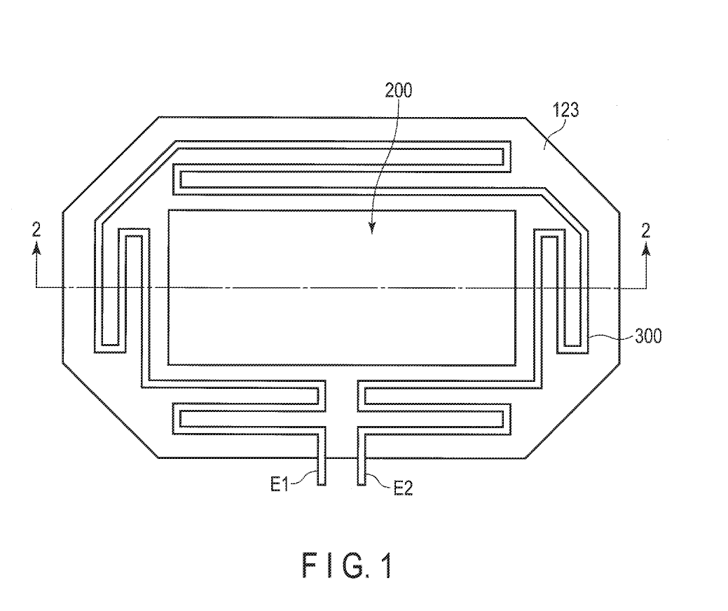

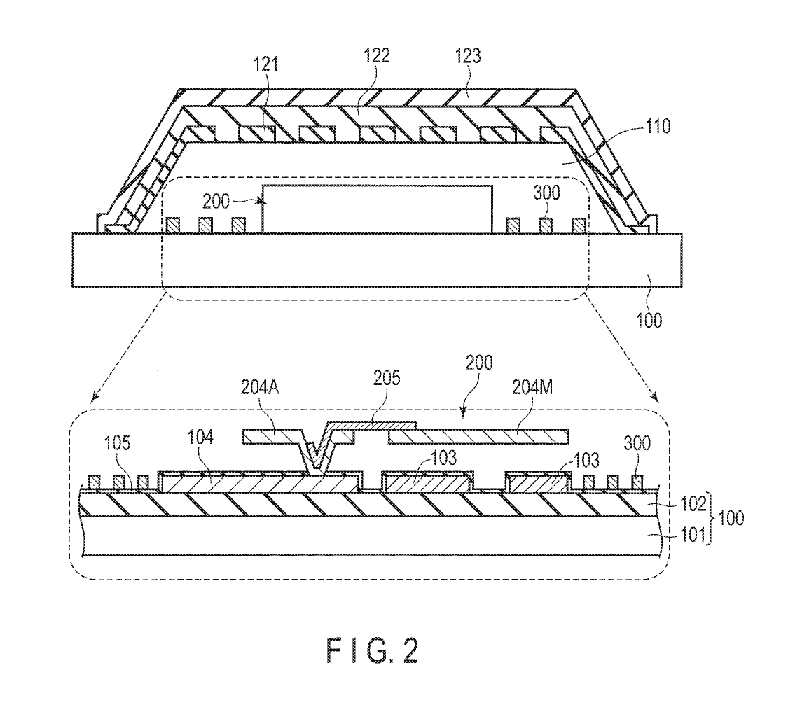

FIG. 1 is a plan view schematically illustrating a device according to a first embodiment. FIG. 2 is a sectional view taken along line 2-2 of FIG. 1.

As shown in FIG. 2, the device of the present embodiment includes a substrate 100, and a MEMS element 200 provided thereon.

The substrate 100 includes, for example, a semiconductor substrate 101, and an insulating film 102 provided on the semiconductor substrate 101. For example, a CMOS integrated circuit (not shown) is formed on the semiconductor substrate 101.

The MEMS element 200 includes a fixed electrode (lower electrode) 103 fixed on the insulating film 102, and a movable electrode (upper electrode) 204M which is provided above the fixed electrode 103 and is vertically (non-horizontally) movable. The MEMS element 200 is used as, for example, a switching element or a capacitor (capacitative element).

An interconnect 104 is provided on the insulating film 102. An insulating film 105 is provided on the fixed electrode 103 and the interconnect 104. The insulating film 105 on the fixed electrode 103 is used as a capacitor insulating film. An anchor portion 204A is provided on the interconnect 104. The anchor portion 204A is connected to the interconnect 104 via a through hole formed in the insulating film 105. The movable electrode 204M and the anchor portion 204A are connected by a spring portion 205.

The device of the present embodiment further includes first to third cap films 121 to 103 provided on the substrate 100 via the insulating film 105. The first to third cap films 121 to 123 constitute a thin-film dome (diaphragm). The substrate 100 and the first to third cap films 121 to 123 constitute a cavity 110 in which the fixed electrode 103, the interconnect 104, a portion of the insulating film 105, the movable electrode 204M, the anchor portion 204A, and the spring portion 205 are housed. The MEMS element 200 is housed in the cavity 110.

The device of the present embodiment further includes a getter member (gas absorption member) 300 provided in the cavity 110. The getter member 300 is disposed on the insulating film 105 in the cavity 110.

A material for the getter member 300 (getter material) includes, for example, titanium (Ti). Ti is a material also used in a CMOS process. Although ZrₓFe_{y} is also a getter material, ZrₓFe_{y} contaminates a CMOS. Accordingly, Ti is preferable for the getter material.

The getter member 300 may have a single-layer structure of a Ti layer, or may have a stacked structure including a Ti layer and a titanium nitride (TiN) layer provided thereon. The stacked structure of Ti layer/TiN layer has a following advantage. That is, in a photolithography process, the TiN layer functions as an antireflective film for exposed light, and thus, the getter member 300 with high dimensional accuracy can be formed.

From an inner wall of the cap films 121 to 123 (thin-film dome), gas (for example, O₂ gas (gas of oxygen) or OH gas (gas of OH group (hydroxyl group)) is discharged. The above gas (discharged gas) causes a change of pressure in the thin-film dome over time, and a change of atmosphere in the thin-film dome. These changes may lead to a characteristic change of the MEMS element.

However, in the present embodiment, the discharged gas is absorbed to a surface of the getter member 300, then the discharged gas is diffused into the getter member 300, and the discharged gas is incorporated into the getter member 300. Therefore, the characteristic change of the MEMS element is restrained.

As shown in FIG. 1, the getter member 300 is formed around the MEMS element 200, but does not completely surround the periphery of the MEMS element 200. That is, the getter member 300 comprises one end portion E1 and other end portion E2. A portion between the one end portion E1 and the other end portion E2 of the getter member 300 has a pattern bending in a zigzag (zigzag pattern). The zigzag pattern includes, for example, a meander pattern. This is intended to enlarge the area of the getter member 300 so that a large quantity of discharged gas can be absorbed.

The one end portion E1 and the other end portion E2 of the getter member 300 are connected to a direct current source not shown in the figures. When a current supplied from the current source flows through the getter member 300, the getter member 300 generates heat.

The reason to enable the getter member 300 to generate the heat is to reduce titanium oxide on the surface of the getter member 300. As will be described later, titanium oxide is formed on the surface of the getter member 300 in a process for manufacturing the MEMS element.

Titanium oxide on the surface of the getter member 300 prevents the getter member 300 from incorporating the discharged gas.

Thus, in the present embodiment, after the MEMS element is manufactured, the current is made to flow through the getter member 300 to enable the getter member 300 to generate the heat, thereby heating the titanium oxide formed on the surface of the getter member 300. The heated titanium oxide is activated, then oxide is separated from the titanium oxide, and the titanium oxide on the surface of the getter member 300 is reduced.

In order to activate the titanium oxide, the temperature of the getter member 300 is needed to be raised up to, for example, about 500-700° C. When temperature of the MEMS element is raised up to about 500-700° C., the MEMS element may be deteriorated. Accordingly, it is important to raise the temperature of the getter member 300 without heating the MEMS element. In the present embodiment, the temperature of the getter member 300 can be selectively raised by making the current flow through the getter member 300.

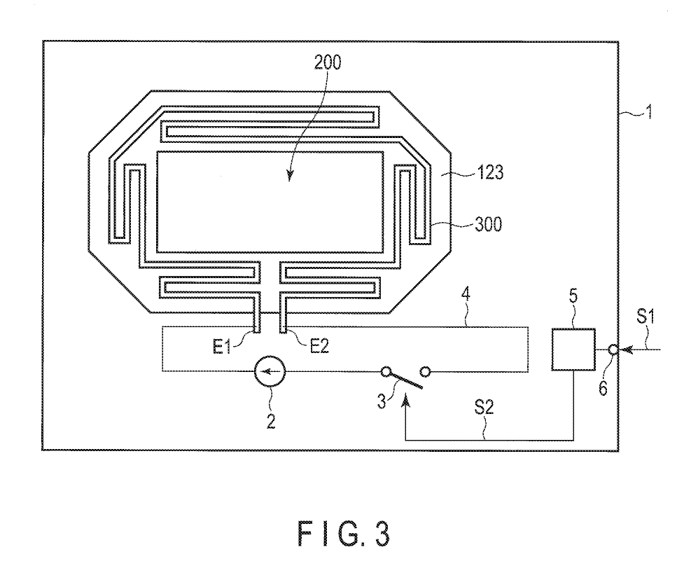

FIG. 3 is a view for explaining an example of the device comprising a mechanism for enabling a current to flow through a getter member 300.

This device comprises a chip 1. The chip 1 includes the device (MEMS device) shown in FIG. 2, and further includes a direct current power source 2, a switch 3, an interconnect 4, a control circuit 5, and an input terminal 6 as well.

The one end portion E1 and the other end portion E2 of the getter member 300 are connected to the direct current power source 2 by the interconnect 4. The switch 3 is provided in a middle of the interconnect 4. The state (open/close) of switch 3 is controlled by a control signal S2 from the control circuit 5. FIG. 3 shows the switch 3 in an open state. The control circuit 5 starts operation based on a signal S1 supplied from outside the chip 1.

It should be noted that the direct current power source 2, the switch 3, the interconnect 4, the control circuit 5, and the input terminal 6 are provided in, for example, a lower layer than the MEMS element 200.

When titanium oxide formed on the surface of the getter member 300 is removed, a signal S1 is first input to the control circuit 5 through the input terminal 6.

When the signal S1 is input, the control circuit 5 generates a control signal S2 for closing the switch 3.

When the switch 3 is closed, a current from the direct current power source 2 is supplied to the getter member 300 through the interconnect 4, and the getter member 300 generates heat.

If it is determined that titanium oxide is removed by the production of heat by the getter member 300, the control circuit 5 generates a control signal S2 for opening the switch 3. The above determination is performed based on, for example, a predetermined time. Specifically, it is examined in advance how long a current needs to flow through the getter member 300 to reduce titanium oxide. In general, the larger the current flowing through the getter member 300 is, the shorter the time during which the current needs to flow is.

The control circuit 5 monitors an elapsed time from when generating the control signal S2 for closing the switch 3, and when the predetermined time has elapsed, the control circuit 5 generates a control signal S2 for opening the switch 3.

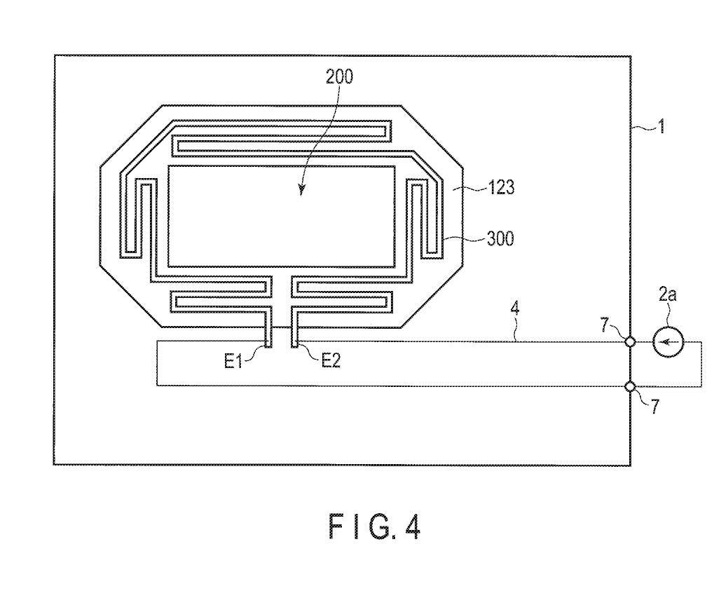

FIG. 4 is a diagram for explaining another example of the device comprising the mechanism for enabling the current to flow through the getter member 300.

This device enables a current to flow through the getter member by using an external direct current power source 2a. The external direct current power source 2a is provided outside the chip 1. The chip 1 comprises two pads (external pads) 7. By connecting the external direct current power source 2a to the external pads 7, a current from the external direct current power source 2a is supplied to the getter member 300 through the interconnect 4, and the getter member 300 generates heat.

It should be noted that the interconnect 4 and the pads 7 are provided in, for example, a higher layer than the MEMS element 200. The chip may comprise one pad or more than two pads.

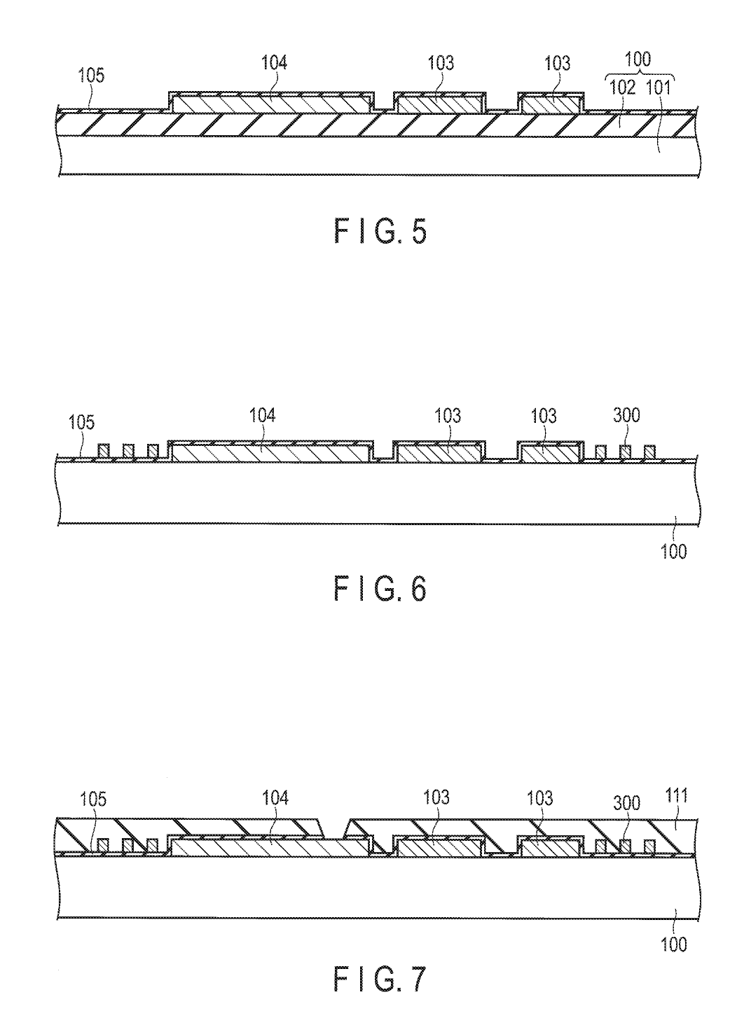

The device of the present embodiment will be further described hereinafter in accordance with a method for manufacturing the same.

[FIG. 5]

First, using a well-known process, the insulating film 102 is formed on the semiconductor substrate 101, then the fixed electrode 103 and the interconnect 104 are formed on the insulating film 102, and further, the insulating film 105 is formed on a region including the insulating film 102, the fixed electrode 103 and the interconnect 104.

The semiconductor substrate 101 is, for example, a silicon substrate. The insulating film 102 is, for example, a silicon oxide film. Materials for the fixed electrode 103 and the interconnect 104 include, for example, aluminum (Al). The fixed electrode 103 may be, for example, a stacked body of a Ti layer, an Al alloy layer, and a Ti layer. The insulating film 105 is formed using, for example, a CVD process. The insulating film 105 is, for example, a silicon oxide film, a silicon nitride film or the like.

It should be noted that in the following figures, the semiconductor substrate 101 and the insulating film 102 of FIG. 5 are shown together as the one substrate 100 for simplification.

[FIG. 6]

A titanium film to be processed into the getter member 300 is formed on the insulating film 105, thereafter, the titanium film is processed by photolithographic process and etching process, whereby the getter member 300 is formed. In the photolithographic process, a resist pattern used as a mask is formed. The etching process is, for example, a reactive ion etching (RIE) process. The above resist pattern is removed by oxygen ashing after the etching process. The oxygen ashing causes titanium oxide to be generated on the surface of the getter member 300.

[FIG. 7]

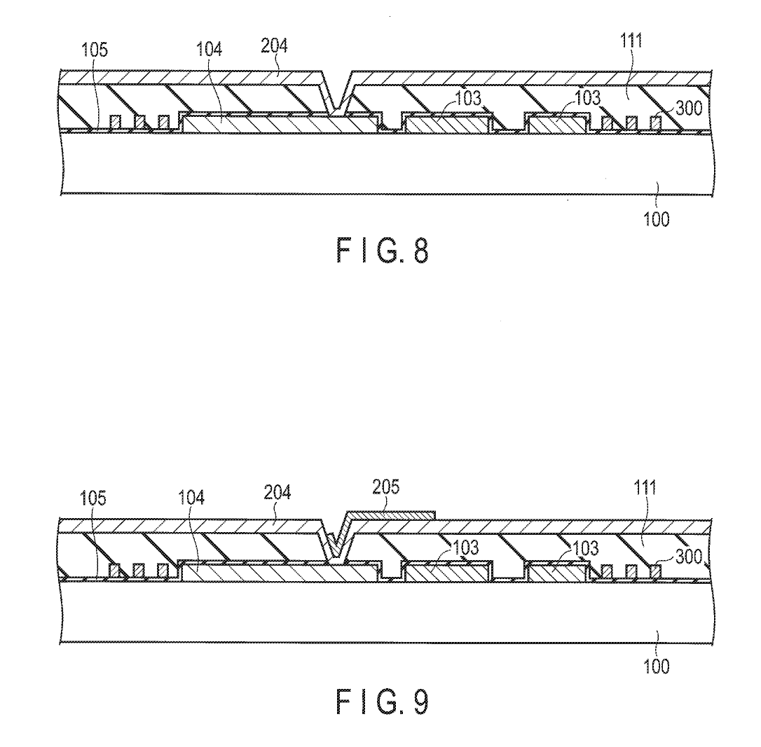

A first sacrifice film 111 is formed on the insulating film 105 and the getter member 300, thereafter, the first sacrifice film 111 and the insulating film 105 are processed by photolithography process and etching process, thereby forming a through hole in the first sacrifice film 111 and the insulating film 105, which communicates with a upper surface of the interconnect 104. The above through hole is formed in a region corresponding to an anchor portion. The first sacrificial film 111 is, for example, an insulating film using an organic material such as polyimide.

[FIG. 8]

A conductive film 204 to be processed into the movable electrode and the anchor portion is formed on the first sacrificial film 111. The conductive film 204 is formed by, for example, a sputtering method. A material for the above conductive film is, for example, Al, an alloy using Al as its main component, Cu, Au, or Pt. A semiconductor film (for example, a Si film or a SiGe film) may be used instead of the conductive film 204.

[FIG. 9]

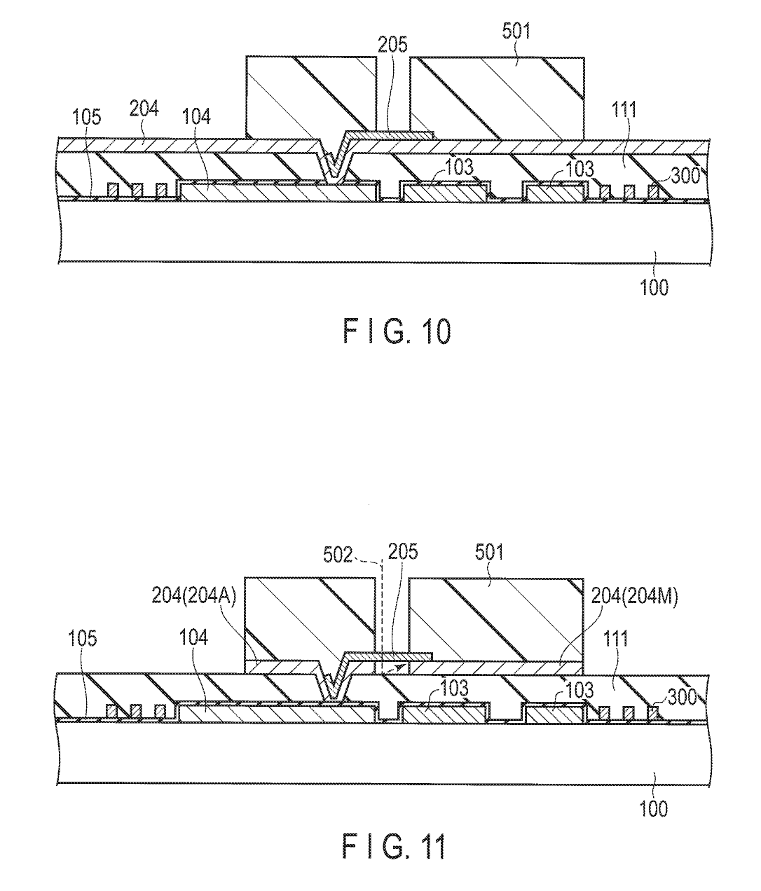

A conductive film to be processed into the spring portion 205 is formed on the conductive film 204, thereafter, the conductive film is processed by using photolithographic process and etching process, whereby the spring portion 205 is formed. Materials for the spring portion 205 and the conductive film 204 may be the same or may be different. In addition, a semiconductor film may be used instead of the conductive film.

[FIG. 10]

A resist pattern 501 is formed on the conductive film 204 and the spring portion 205. The resist pattern 501 has a pattern corresponding to the movable electrode and the anchor portion.

[FIG. 11]

The anchor portion 204A and the movable electrode 204M are formed by patterning the conductive film 204 by wet etching with the resist pattern 501 using as a mask.

The conductive film 204 located below the spring portion 205 not covered with the resist pattern 501 is etched from its side by etchant 502. Thus, the conductive film 204 is divided into the anchor portion 204A and the movable electrode 204M.

It should be noted that the conductive film 204 may be patterned by using an isotropic etching other than wet etching.

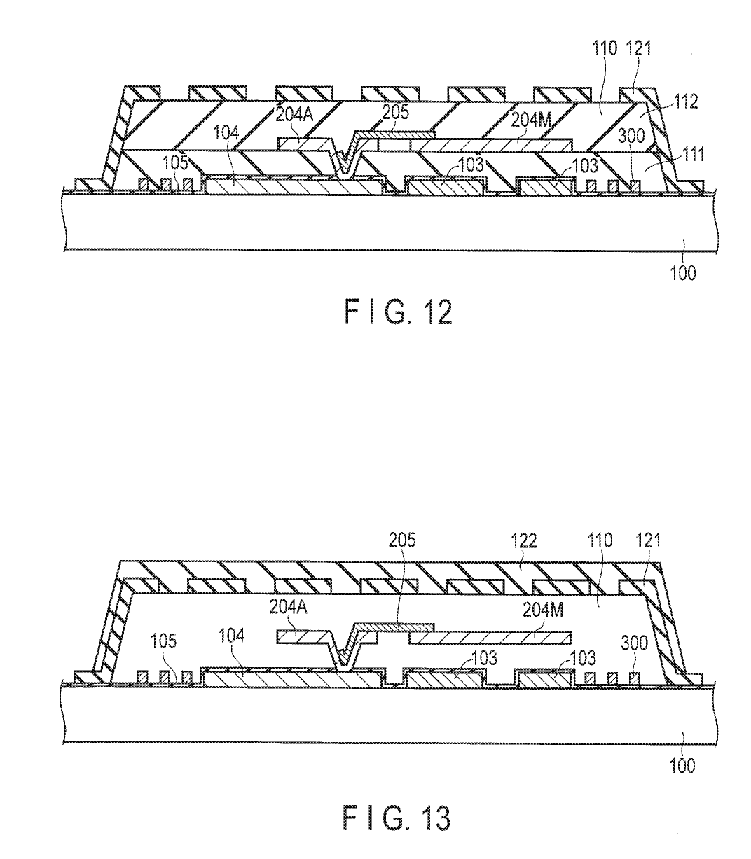

After the anchor portion 204A and the movable electrode 204M are formed, the resist pattern 501 is removed.

[FIG. 12]

A second sacrificial film 112 is formed on the first sacrificial film 111, the anchor portion 204A, the movable electrode 204M and the spring portion 205, thereafter, the first sacrificial film 111 and the second sacrificial film 112 are patterned. The second sacrificial film 112 is, for example, a film (coating film) using organic material such as polyimide, which is formed by coating method.

The first cap film 121 having through holes is formed on the first sacrifice film 111, the second sacrifice film 112 and the insulating film 105. The first cap film 121 is an inorganic thin film (for example, a silicon oxide film). The first cap film 121 is formed by, for example, a CVD process. The through holes are used to supply gas for removing the sacrifice films 111 and 112 into the first cap film 121.

[FIG. 13]

The first sacrificial film 111 and the second sacrificial film 112 shown in FIG. 12 are removed by ashing using oxygen (O₂), etc. Thereby the cavity 110, which is an operating space for the MEMS element, is formed by the substrate 100 and the first cap film 121.

The second cap film 122 is formed on the first cap film 121 by coating method. In the present embodiment, the second cap film 122 is an organic film (insulating film) using organic material such as polyimide system resin. In this case, the second cap film 122 can be formed to fill the through holes of the first cap film 121, and the second cap film 122 has higher gas permeability than the first cap film 121. Even if the second cap film 122 does not fill the first through holes of the first cap film 121, it suffices that the second cap film 122 closes the first through holes.

After that, as shown in FIG. 2, the third cap film 123 is formed on the second cap film 122, whereby the thin-film dome (the cap films 121 to 123) is completed. The third cap film 123 functions as a moisture-proof film. For that purpose, it is preferable that the third cap film 123 have lower gas permeability than the second cap film 122. Such a gas permeability relationship is realized by, for example, using a deposition film by CVD process as the third cap film 123, and using a coating film by spin coating method as the second cap film 122.

Next, the current is made to flow through the getter member 300 for enabling the getter member 300 to generate the heat, thereby activating the titanium oxide on the surface of the getter member 300 to separate the oxide from the titanium oxide.

Although oxygen separated from the titanium oxide is discharged into the thin-film dome (the cap films 121 to 123), the getter member 300 with the reduced titanium oxide can incorporate larger amount of oxygen than the amount of the separated oxygen.

Accordingly, the gas such as oxygen is reduced, which is in the thin-film dome and causes the characteristic change of the MEMS element, and the device including the MEMS device capable of restraining the characteristic change can be provided.

### Second Embodiment

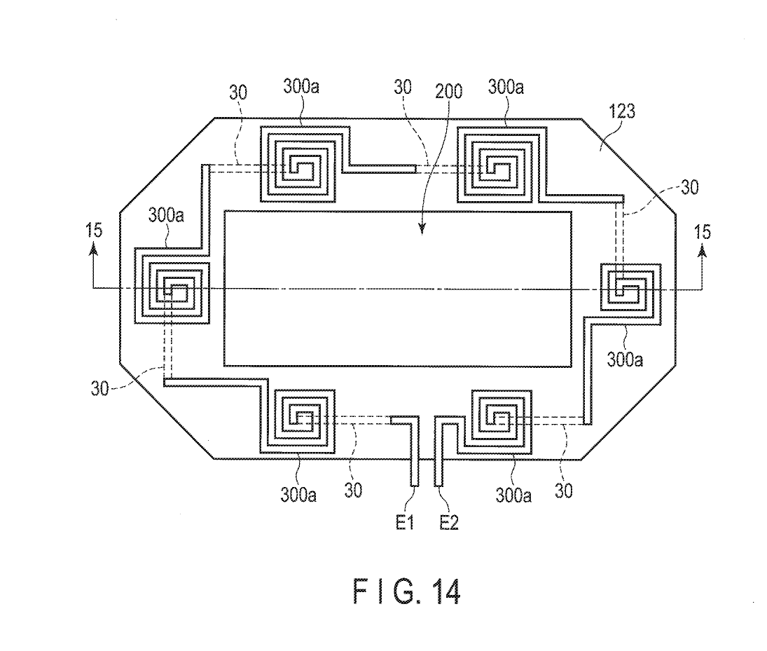

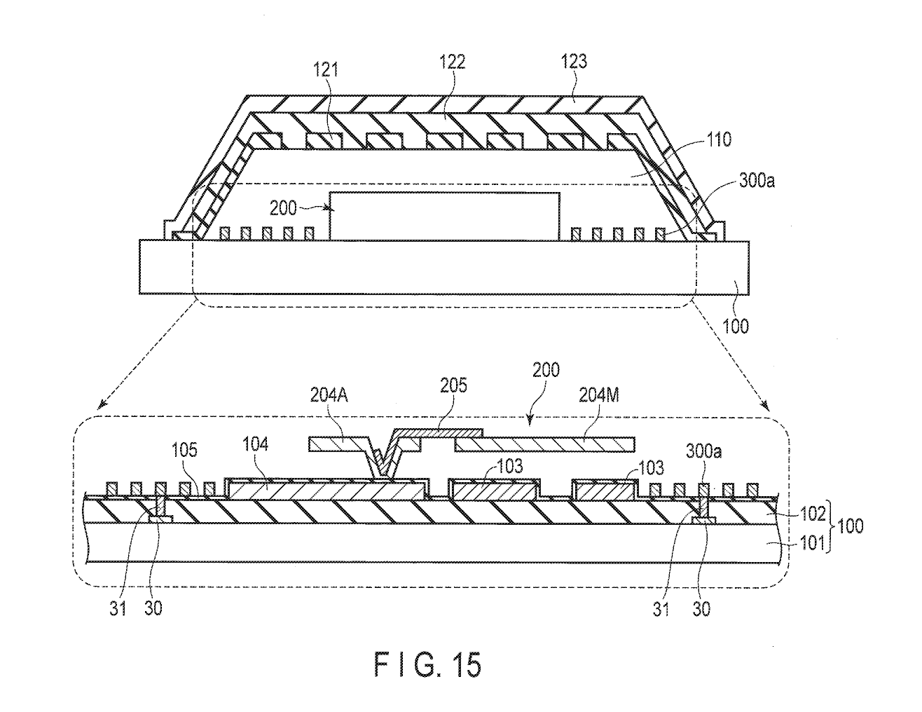

FIG. 14 is a plan view schematically illustrating a MEMS device according to a second embodiment. FIG. 15 is a sectional view taken along line 15-15 of FIG. 14.

The present embodiment differs from the first embodiment in that coiled getter members 300a are used. The coiled getter members 300a are connected by interconnects 30 and vias 31 provided in a substrate 100. Although FIG. 14 shows the six coiled getter members 300a, the number of the getter members 300a is not limited to six.

When a high-frequency current is made to flow through the getter members 300a, a magnetic field is generated around the getter members 300a, and an eddy current is induced by the magnetic field, which flows in the surfaces of the getter members 300a. The titanium oxide on the surfaces of the getter members 300a is heated by the eddy current. Whereby similarly to the first embodiment, the titanium oxide is activated, and the same advantage as that of the first embodiment is obtained.

In order to apply the high-frequency current to the getter members 300a, a modification of the mechanism in FIG. 3 or FIG. 4 may be used for instance, in which the direct current power source in FIG. 3 or FIG. 4 is replaced by a high-frequency alternating current power source.

### Third Embodiment

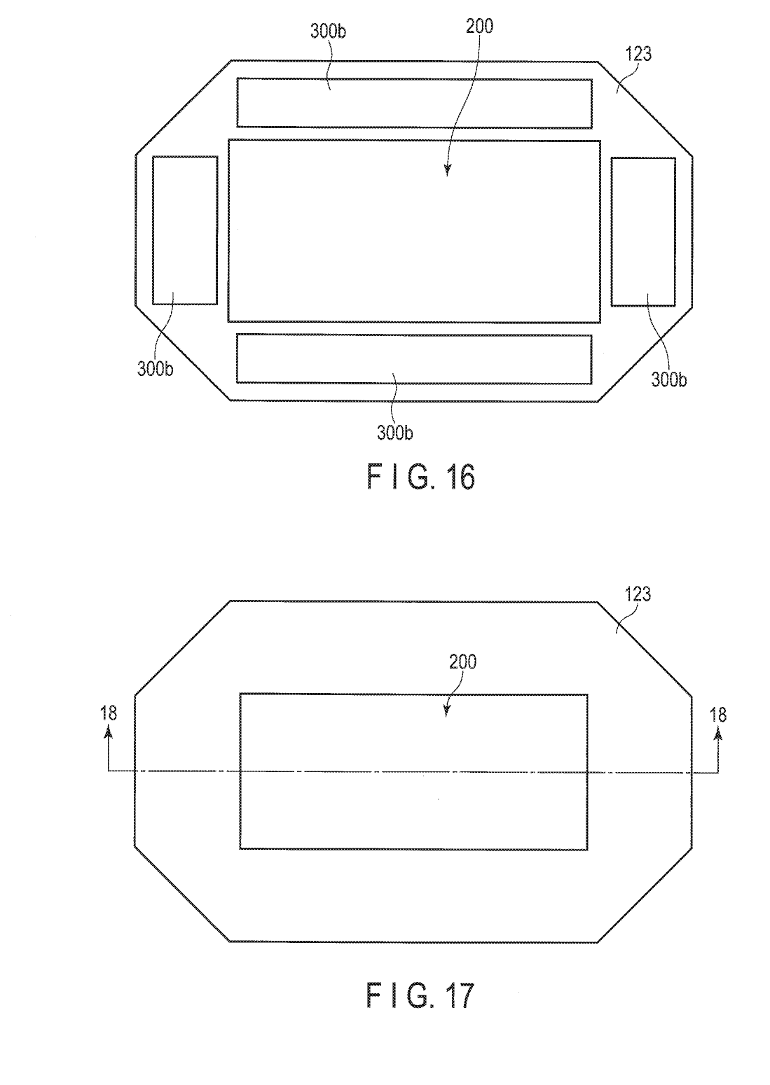

FIG. 16 is a plan view schematically illustrating a MEMS device according to a third embodiment.

The present embodiment differs from the first embodiment in that plate-like getter members 300b are used. Although FIG. 16 shows the four plate-like getter members 300b, the number of the getter members 300b is not limited to four.

The band gap of titanium oxide (TiO₂) is greater than or equal to 3.2 eV. Thus, in the present embodiment, the getter members 300b is irradiated with light (UV light) having a wavelength less than or equal to 400 nm corresponding to the energy greater than or equal to 3.2 eV. Titanium oxide irradiated with the UV light is activated, then the oxide is separated from the titanium oxide, and the titanium oxide on the surface of the getter members 300b is reduced.

The irradiation of UV light is performed, for example, after the second cap film 122 is formed, or after the third cap film 123 is formed.

### Fourth Embodiment

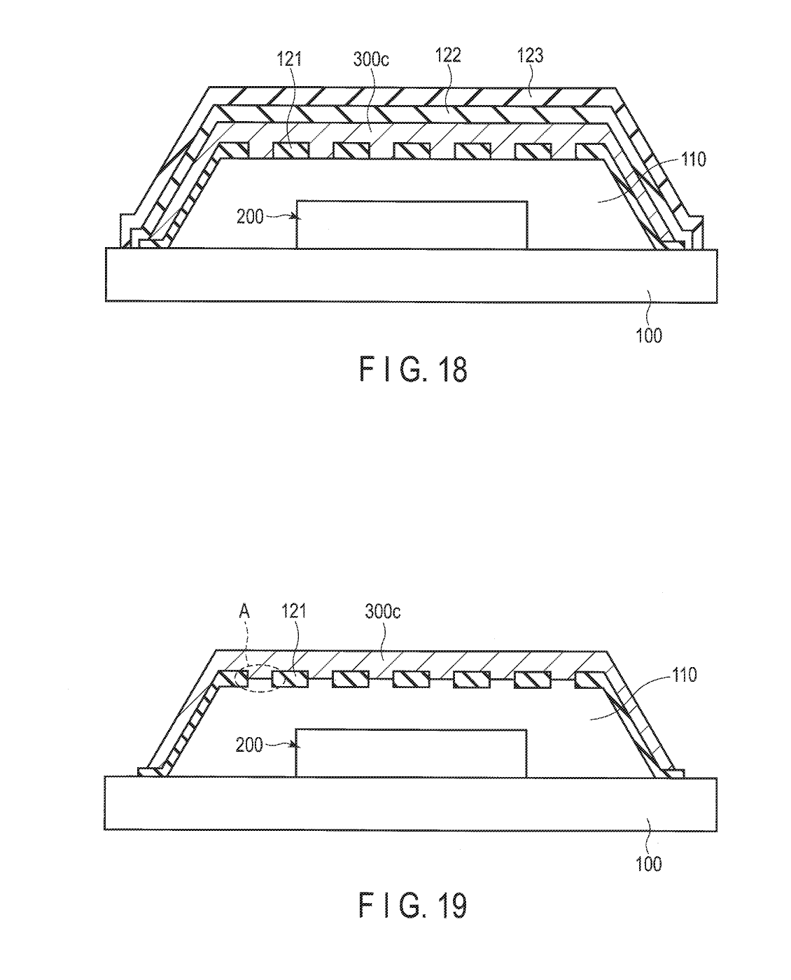

FIG. 17 is a plan view schematically illustrating a MEMS device according to a fourth embodiment. FIG. 18 is a sectional view taken along line 18-18 of FIG. 17.

The present embodiment differs from the first embodiment in that a getter member 300c is provided in a thin-film dome (cap films 121 to 123). A portion of the getter member 300c is exposed to a cavity 110.

Specifically, the getter member 300c is provided on the first cap film 121, and the second cap film 122 and the third cap film 123 are sequentially provided on the getter member 300c. The getter member 300c in the through holes of the first cap film 121 is exposed to the cavity 110.

In order to form the getter member 300c, after the step of FIG. 12, a film of the getter material is formed as shown in FIG. 19, thereafter, the film is process by photolithographic process and etching process, whereby the getter member 300c is formed.

The film of the getter material is formed by, for example, a sputtering process. In order to prevent the getter material from passing through the through holes of the first cap film 121, for example, the following action is taken. The through holes of the first cap film 121 are made small in diameter, and the sputtering process is performed in an atmosphere with a high degree of vacuum. Whereby the characteristic change of a MEMS element 200 caused by the deposition of the getter material on the MEMS element 200 is prevented.

After the getter member 300c is formed, the resist pattern formed in the above photolithographic process is removed by oxygen ashing. In the oxygen ashing, the surface of the getter member 300c outside the cavity 110 is exposed to oxygen, but a portion of the getter member 300c, which contacts the cavity 110 (vacuum space), is not exposed to the oxygen. Accordingly, in the present embodiment, a step for removing the titanium oxide from the surface of the getter member 300c is unnecessary.

It should be noted that in FIG. 19, the sectional shape of the getter member 300c in the through holes of the first cap film 121, enclosed by a broken line A, is a rectangle, and the surface of the getter member 300c contacting the cavity 110 (vacuum space) is constituted of one plane surface. However, the sectional shape may be those other than a rectangle, and the surface of the getter member 300c contacting the cavity 110 may be constituted of two or more plane surfaces, or one or more curved surfaces.

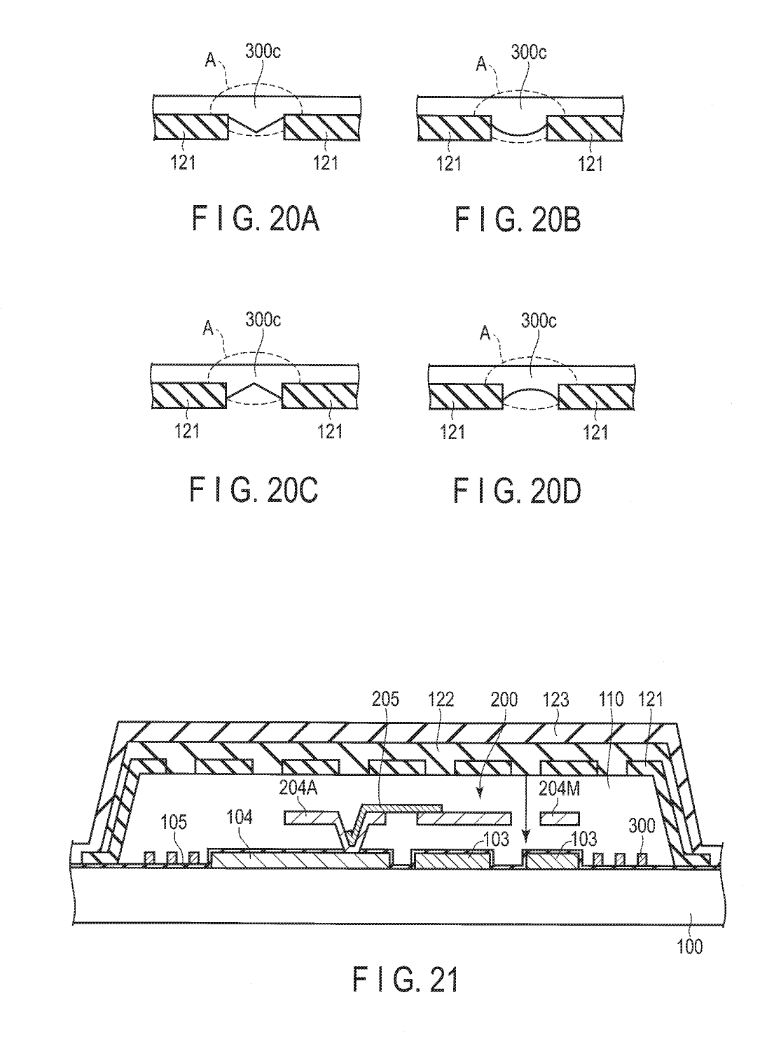

For example, if a getter material with high viscosity is used, the sectional shape of the getter member 300c in the through holes is convex downward as shown in FIG. 20A and FIG. 20B. FIG. 20A illustrates the sectional shape of a V-shape, and FIG. 20B shows the sectional shape of a curved surface convex downward.

Conversely, if a getter member with low viscosity is used, the sectional shape of the getter member 300c in the through holes is, for example, convex upward as shown in FIG. 20C and FIG. 20D. FIG. 20C shows the sectional shape of a reverse V-shape, and FIG. 20D shows the sectional shape of a curved surface convex upward.

In this manner, the surface of the getter member 300c in the through holes of the first cap film 121, which contacts the cavity 110, includes two bent plane surfaces or one curved surface as shown in FIG. 20A to FIG. 20D, whereby an area of the getter member 300c in the through holes contacts the cavity 110 can be made larger. The function (gas absorption) of the getter member 300c can be thereby enhanced.

It should be noted that the second cap film 122 may be omitted since the getter member 300c seals the through holes of the first cap films 121 in the present embodiment.

FIG. 21 is a sectional view illustrating a device including a variation of the MEMS element 200 of the present embodiment.

A movable electrode 204M of the MEMS element 200 of the variation has a through hole. Although FIG. 21 illustrates an example of one through hole, the number of through holes is not limited to one.

In the MEMS element 200 of the variation, the through hole of the first cap film 121 exists above the through hole of the movable electrode 204M. Therefore, even if the getter material enters the cavity 110 from the through hole of the first cap film 121 above the through hole of the movable electrode 204M as indicated by an arrow in FIG. 21, the getter material passes through the through hole of the movable electrode 204M and is deposited on an insulating film 105 in a region not functioning as a fixed electrode 103 of a capacitor.

That is, the getter material entering the cavity 110 from the through hole of the first cap film 121 can be restrained from being deposited on the movable electrode 204M and the fixed electrode 103. Decreases in the performance and reliability of the MEMS element 200 due to the deposition of the getter material are thereby restrained.

In addition, the through hole of the movable electrode 204M can be used as an inlet of the gas for removing the sacrificial film 111 under the movable electrode 204M in the step of FIG. 13, and the removal of the first sacrificial film 111 is facilitated.

It should be noted that the through hole also may be provided in the anchor portion 204A as well as the movable electrode 204M.

Although a getter member is provided on the substrate or in the cap films in the above-described embodiments, the getter member may be provided to other places. However, the getter member is required to include a portion exposed to the cavity in order that the getter member exhibits its function (gas adsorption).

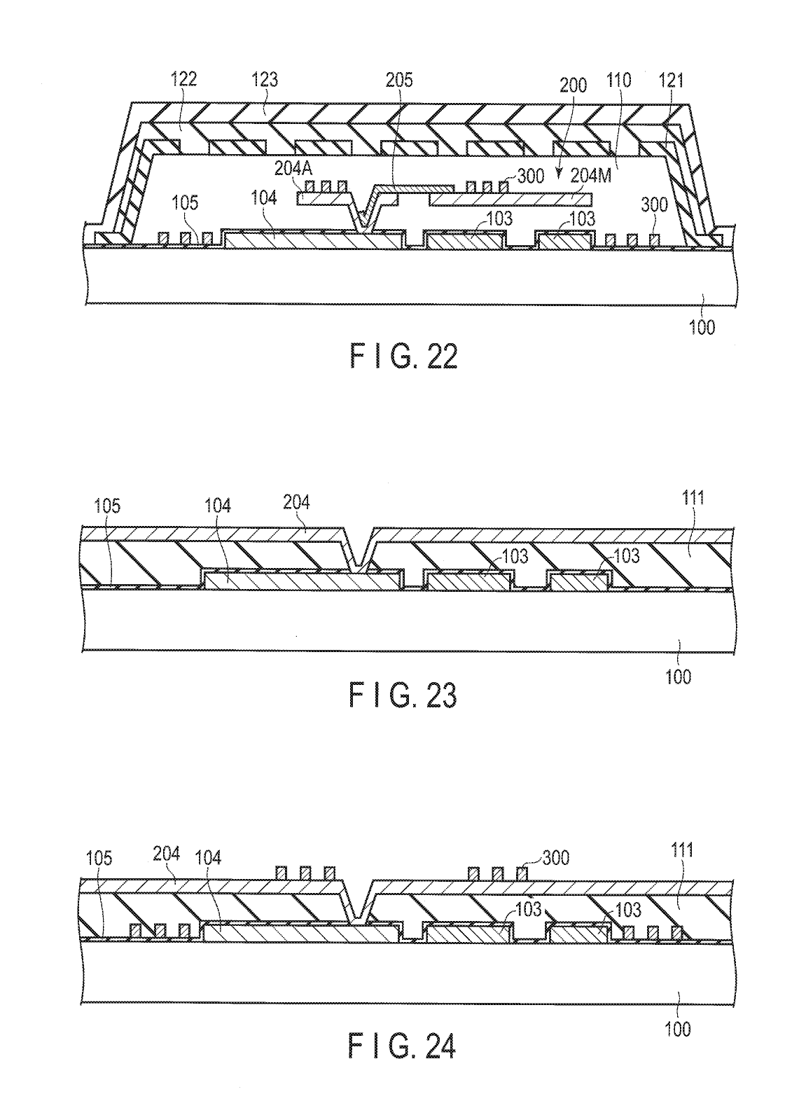

As for an installation location of the getter member, other than the substrate and the cap films, for example, as shown FIG. 22, the anchor portion 204A and the movable electrode 204A are served. In order to obtain the device having the getter member 300 on the anchor portion 204A and the movable electrode 204A, the steps of FIG. 23 and FIG. 24 are carried out subsequent to the step of FIG. 5, for instance.

In FIG. 23, a first sacrificial film 111 having a through hole communicating with the interconnect 104, and a conductive film 204 are formed on the insulating film 105.

In FIG. 24, a film to be processed into the getter member 300 is formed on the conductive film 204, thereafter, the film is processed by photolithography process and etching process, whereby the getter member 300d is formed on the conductive film 204 in a region where the anchor portion and the movable electrode are to be formed. Thereafter, the device shown in FIG. 22 is obtained by carrying out steps corresponding to the step of FIG. 9 and the steps after FIG. 9.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A device comprising:
a substrate;
an element provided on the substrate;
a film provided on the substrate, the film and the substrate constituting a cavity in which the element is housed; and
a gas absorbing member having a pattern, provided in the cavity, and including a portion exposed to the cavity.

2. The device according to claim 1, wherein the pattern comprises a meander pattern.

3. The device according to claim 1, wherein the gas absorption member generates heat when a direct current flows through the gas absorption member.

4. The device according to claim 1, wherein the pattern comprises a coiled pattern.

5. The device according to claim 4, wherein the gas absorption member generates heat when an alternating current flows through the gas absorption member.

6. The device according to claim 1, further comprising a current source to supply a current to the gas absorption member.

7. The device according to claim 1, further comprising a pad to be connected to an external current source for supplying a current to the gas absorption member.

8. The device according to claim 1, wherein the pattern comprises a plate-like pattern.

9. The device according to claim 8, wherein the gas absorption member is activated when the gas absorbing member is irradiated with light.

10. The device according to claim 1, wherein the gas absorption member is disposed outside the element on the substrate.

11. The device according to claim 1, wherein the film includes a first film having a plurality of through holes, and a second film provided on the first film and facing the plurality of through holes.

12. The device according to claim 1, wherein the film further includes a third film provided on the second film,
the second film has higher gas permeability than the first film, and
the third film has lower gas permeability than the second film.

13. The device according to claim 1, wherein the gas absorption member includes a layer of titanium.

14. The device according to claim 13, wherein the gas absorption member further includes a layer of titanium nitride provided on the layer of titanium.

15. The device according to claim 1, wherein the gas absorption member absorbs gas of oxygen or hydroxyl group.

16. The device according to claim 1, wherein the element includes a first electrode fixed on the substrate, and a second electrode disposed above the first electrode and being movable in a non-horizontal direction.

17. A device comprising:
a substrate;
an element provided on the substrate;
a film provided on the substrate, the film and the substrate constituting a cavity in which the element is housed; and
a gas absorption member provided in the film, and including a portion exposed to the cavity.

18. The device according to claim 17, wherein the film includes a first film having a through hole and a second film provided on the first film, and
the gas absorption member is provided between the first film and the second film, and closes the through holes of the first film.

19. The device according to claim 18, wherein the gas absorbing member in the through hole includes a surface in contact with the cavity, and the surface includes at least two flat surfaces, or at least one curved surface.

20. The device according to claim 19, wherein a cross-sectional shape of the gas absorbing member in the through hole in parallel to a depth direction of the through hole includes a V-shape or a convex-shape.
